(19) United States
(12) Patent Application Publication
(10) Pub. No.: US 2018/0033636 A1
(43) Pub. Date: Feb. 1, 2018

(54) METHOD OF FABRICATING A SEMICONDUCTOR STRUCTURE

(71) Applicant: UNITED MICROELECTRONICS CORP., Hsin-Chu City (TW)

(72) Inventors: Li-Chieh Hsu, Taichung City (TW); Fu-Shou Tsai, Keelung City (TW); Yu-Ting Li, Chiayi City (TW); Po-Cheng Huang, Kaohsiung City (TW); Yi-Liang Liu, Tainan City (TW); Wen-Chin Lin, Tainan City (TW); Chun-Yi Wang, Chang-Hua Hsien (TW); Chun-Yuan Wu, Yun-Lin County (TW)

(21) Appl. No.: 15/221,586

(22) Filed: Jul. 27, 2016

(51) Int. Cl. H01L 21/3105; H01L 21/02

(52) U.S. Cl. CPC H01L 21/31053; H01L 21/0217; H01L 21/0214; H01L 21/02167; H01L 21/02126; H01L 21/02065

(57) ABSTRACT

A method of fabricating a semiconductor structure is provided. A substrate surface is provided and a first layer is disposed on the substrate surface. A second layer covering the first layer is formed wherein the materials of the first layer and the second layer are different. A first polishing operation is performed on the second layer until a first polished surface exposing a portion of the first layer is obtained. A second polishing operation is performed on the first polished surface to obtain a second polished surface wherein an upper portion of the exposed portion of the first layer is removed. None of the substrate is exposed from the first polished surface and the second polished surface.

### BACKGROUND OF THE INVENTION

### 1. Field of the Invention

The invention generally relates to a method of fabricating a semiconductor structure. More particularly, the invention relates to a method of fabricating a semiconductor structure having a planarized top surface with reduced defects.

### 2. Description of the Prior Art

As known in the art, integrated circuits are typically formed by a series of process steps in which multiple patterned layers of materials, such as conductive, insulating and semiconductor materials, are formed on a semiconductor substrate. As the IC industry processes through each successive technology node on the ITRS roadmap, the complexity of the integrated circuit structure has become higher with an increasing number of stacked patterned layers. A patterned layer formed on the substrate may cause a non-flat top surface, which is not preferred for subsequent processes, especially for a photolithography process since a non-flat top surface may cause defocus and poor resolution.

The degree of non-flatness would get worse if layers are stacked as the process continues but no planarization process is performed. In the advanced semiconductor technology, it has been one of the most important tasks to provide a leveled surface for subsequent fabrication steps.

Chemical mechanical polish (CMP) processes are widely used in modern semiconductor technology due to good performance in planarization. CMP processes are carried out by placing a wafer in a carrier that presses the wafer surface with a proper force against a polish pad fixed on a platen. Both the platen and the wafer carrier are rotated while slurry comprising abrasive particles and additives, such as surfactants, polymeric stabilizers or other surface active dispersing agents, pH adjusters, regulators, buffers and the like, is introduced into the space between the polish pad and the wafer surface. The abrasive particles polish away the excess material both chemically and mechanically with the assistance from the reactive chemical additives and the relative movement of the polish pad and the wafer surface.

Intensive effort has been made to optimize the performance of the CMP process. The Hybrid CMP technique is developed and well known for its outstanding planarization performance which is achieved by using a slurry with high removal selectivity among different materials, wherein a material with lower removal rate is used as a stop layer to prevent over-polish until the overall surface is planarized. The hybrid CMP technique has gradually taken the place of conventional CMP in critical layers of advanced semiconductor manufacturing.

However, because of the instinct characteristic of the CMP process, the wafer surface is substantially exposed to an environment comprising a lot of particles which may be the removed materials or the reaction by-product of the compositions of the slurry during the polishing. Unavoidably, some of the particles may be absorbed or adhered onto the wafer surface. Although a conventional wet clean (solvent clean) step is usually performed after CMP process in order to remove the attached particles, for some stubborn particles, the efficiency of the wet clean seems not enough. The particles issue is even worse for these critical layers adopting the hybrid CMP technique because the composition of the slurry used in the hybrid CMP technique is usually more complicated and comprises polymers which may form particles that are hard to be removed.

The remaining particles may cause defects or structure deformation to the semiconductor device, resulting in yield loss. Since it has been a well-known concern that the wet clean step with strong particle removal ability may cause undesired material loss or step height between different materials due to different wet etching removal rates, the use of a wet clean with strong particle removal ability is limited. Therefore, there is still a need in the field to provide a method of defect reduction of the CMP process.

### SUMMARY OF THE INVENTION

It is one objective of the present invention to provide a method of fabricating a semiconductor structure having a planarized top surface with reduced defects attached thereon. It may be achieved by employing a hybrid CMP technique followed by an in-situ (in the same processing platform) buff polishing operation which is aimed for defection reduction.

According to one embodiment of the present invention, a method of fabricating a semiconductor structure is provided. First, a substrate surface is provided and a first layer is disposed on the substrate surface. Then, a second layer covering the first layer is formed wherein the materials of the first layer and the second layer are different. Subsequently, a first polishing operation is performed on the second layer until a first polished surface exposing a portion of the first layer is obtained. After that, a second polishing operation is performed on the first polished surface to obtain a second polished surface wherein an upper portion of the exposed portion of the first layer is removed. None of the substrate is exposed from the first polished surface and the second polished surface.

According to one embodiment of the present invention, a particle is formed and adhered onto the first polished surface after the first polishing operation. The particle is completely removed by the second polishing operation.

According to one embodiment of the present invention, the thickness of the removed upper portion of the first layer during the second polishing operation is less than 75 Å.

The advantageous features of the present invention include that the particles attached on the surface may be removed conveniently by the second polishing operation which is carried out in the same platform. Furthermore, the concerns of undesired material loss or step height resulting from using a strong wet clean method are eliminated, which means that the planar surface obtain by the first polishing operation is still maintained after the second polishing operation.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view illustrating a chemical mechanical polish (CMP) platform for performing the embodiments of the present invention;

FIG. 2 is a schematic cross-sectional view illustrating the configuration when a substrate is undergoing a CMP process in the CMP platform as shown in FIG. 1;

FIG. 3 is a schematic cross-sectional view illustrating a substrate having a non-planar top surface according to one embodiment of the present invention;

FIG. 4 to FIG. 8 are schematic cross-sectional views illustrating the substrate as shown in FIG. 3 being processed by a series of polishing operations according to one embodiment of the present invention;

FIG. 9 is a schematic cross-sectional view illustrating the substrate being processed by an additional etching back step after the successive polishing operations; and

FIG. 10 to FIG. 11 are schematic cross-sectional views illustrating a substrate having a non-continuous first layer according to another embodiment of the present invention.

### DETAILED DESCRIPTION

In the following description, numerous specific details are given to provide a thorough understanding of the invention. It will, however, be apparent to one skilled in the art that the invention may be practiced without these specific details. Furthermore, some well-known configurations and process steps are not disclosed in detail, as these should be well-known to those skilled in the art.

Likewise, the drawings showing embodiments of the device are semi-diagrammatic and not to scale and some dimensions are exaggerated in the figures for clarity of presentation. Also, where multiple embodiments are disclosed and described as having some features in common, like or similar features will usually be described with like reference numerals for ease of illustration and description thereof.

The term “substrate” used herein is understood to include any structure having an exposed top surface, but not limited thereto. The term substrate is also used to refer to semiconductor structures during processing, and may include other layers that have been fabricated thereupon.

The term “selectivity” in the following description refers to the ratio of removal rates of two or more materials during CMP process. For example, the selectivity of silicon oxide (SiO₂) to silicon nitride (SiN) represents the ratio of the removal rate of silicon oxide to the removal rate of silicon nitride.

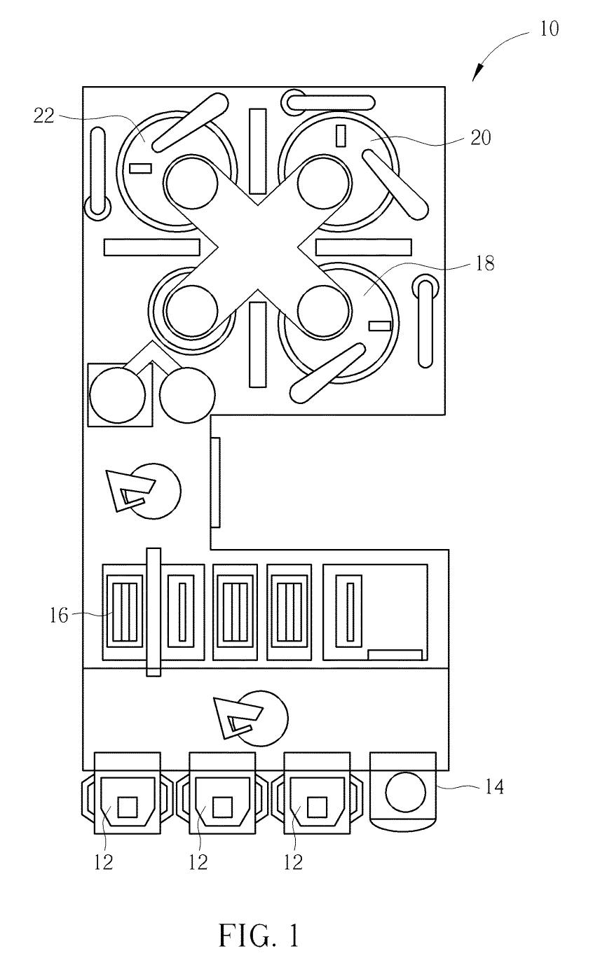

Please refer to FIG. 1. As shown in FIG. 1, a CMP platform 10 for performing the embodiments of the present invention is provided. The CMP platform 10 may comprise at least one loading port 12, a metrology zone 14, a cleaning zone 16, a first platen 18, a second platen 20 and a third platen 22.

The loading port 12 is used for loading/unloading a substrate, such as a semiconductor wafer, into/out from the CMP platform 10. The metrology zone 14 is used to provide the thickness data of layers to be polished. The cleaning zone 16 may comprise solvent or solutions used to clean the substrates after the CMP process. The first platen 18, the second platen 20 and the third platen 22 are places where the CMP process is actually carried on. Each one of the platens is configured to mount a polishing pad while the substrate to be polished is held by a carrier and pressed against the polishing pad. The detailed configuration will be illustrated in the following description.

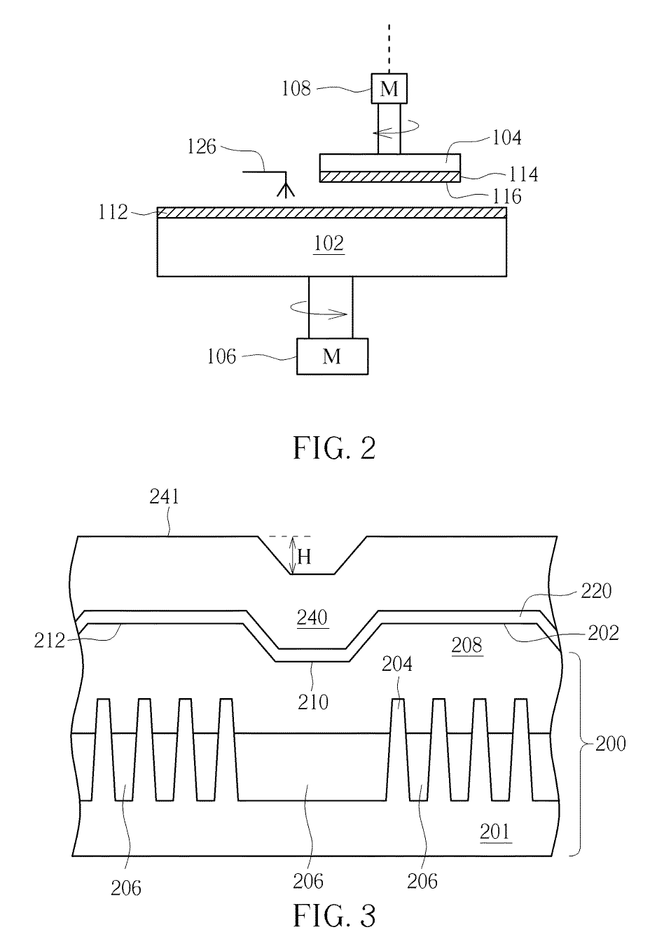

Please refer to FIG. 2, which is a schematic cross-sectional view illustrating the configuration when a substrate is undergoing a CMP process in the CMP platform as shown in FIG. 1. As shown in FIG. 2, a polishing pad 112 is mounted on a platen 102. A substrate 114, such as a semiconductor wafer, is retained upside down by a carrier 104 as the surface 116 to be polished facing toward the polishing pad 112. During the CMP process, the polishing pad 112 polishes the surface 116 of the substrate 114 when the carrier 104 and the platen 102 are brought into proximity and rotated in a relative movement by their respective drive system 106 and 108. Meanwhile, a dispenser 126, such as a spray nozzle, is used to introduce liquid onto the polish pad 112. The liquid may be deionized water (DIW), slurry or pad conditioner.

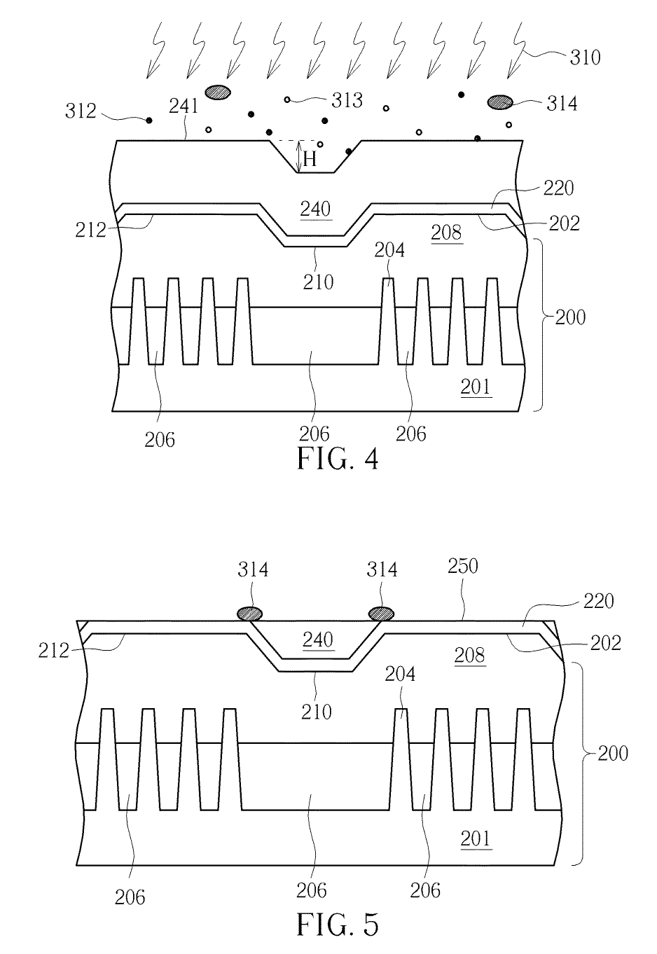

Please refer to FIG. 3, which is a schematic cross-sectional view illustrating a substrate which has a non-planar top surface and will be planarized by a CMP process according to one embodiment of the present invention.

As shown in FIG. 3, a substrate 200 having a substrate surface 202 is provided. The substrate 200 may be a semiconductor wafer or a SOI wafer comprising Si or other suitable materials. The substrate 200 may be an intermediate structure of a semiconductor device on which further processes may be performed to form other structures. One skilled in the art should be able to realize that the substrate 200 may comprise multilayers and pre-formed structures which are configured to be parts of the semiconductor device. According to the embodiment as shown in FIG. 3, the substrate 200 may comprise a semiconductor substrate 201, fin-shaped structures 204 formed in the semiconductor substrate 201, isolation structures 206, such as shallow trench isolation (STI), and a material layer 208, such as amorous silicon, which is disposed atop the fin-shaped structures 204 and the isolation structures 206. In the embodiment, the substrate surface 202 is substantially the top surface of the material layer 208. The substrate surface 202 may be non-planar, having a topography comprising plateau regions 212 and recess regions 210. It should be understood that the substrate 200 as shown in FIG. 3 is for illustration only, and not to be a limitation for the present invention. The present invention may also be applicable to planarize a substrate in a different manufacturing stage of a semiconductor device, such as STI formation in front-end of the line (FEOL) process, or metal interconnection formation in back-end of the line (BEOL) process.

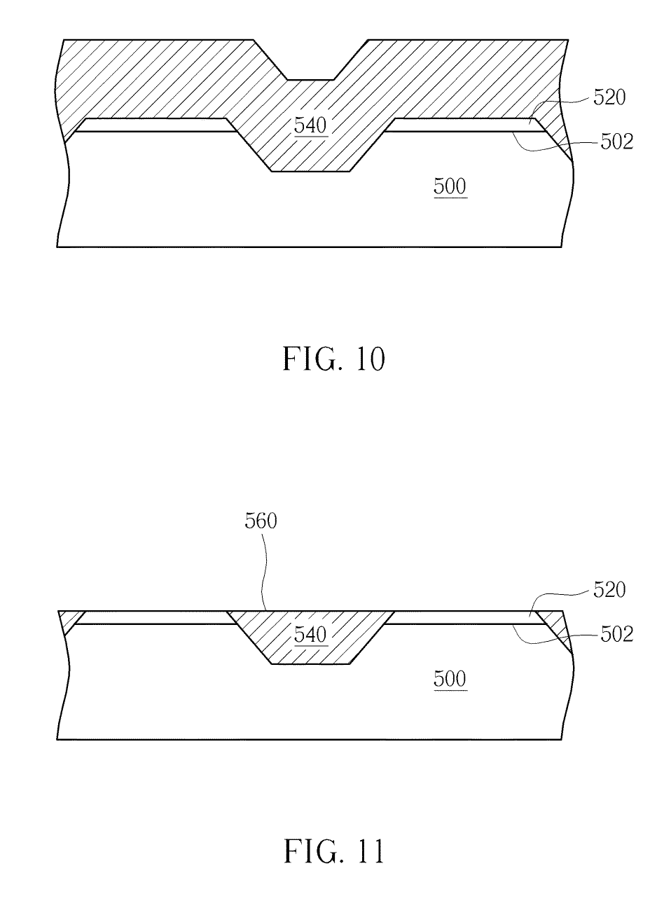

Still refer to FIG. 3. A first layer 220 with a material different from that of the material layer 208 (or different from the substrate 200 when the first layer 220 is directly on the substrate 200) is disposed over the substrate 200. Subsequently, a second layer 240 with a material different from that of the first layer 220 is disposed over the first layer 220. According to the embodiment, the first layer 220 may conformally and completely cover the substrate surface 202 therefore the second layer 240 is not in direct contact with the substrate 200. But in other embodiments, as shown in FIG. 10, the first layer 520 may be non-continuous and only disposed on particular regions of the substrate surface 502, such as on the plateau regions of the substrate surface 502. In such cases, the second layer 540 is in direct contact with the substrate 500 not covered by the first layer 520. The embodiment would be illustrated later in the specification.

The first layer 220 may comprise silicon nitride (SiN), silicon oxynitride (SiON), SiCN, SiOCN or a combination thereof which has significant lower removal rate than the second layer 240 during the following first polishing operation 310. The second layer 240 may comprise SiO₂, polycrystalline silicon, amorphous silicon or other materials according to different applications of the present invention.

According to the embodiment, the topographic features of the substrate surface 202 may be inherited by the first layer 220 and the second layer 240, resulting in a step height H formed between the high topography and low topography regions the top surface 241 of the second layer 240. Preferably, the second layer 240 has a thickness at least larger than the depth of the recess portions 210, and covers up all the topographic variations through the substrate surface 202 with a sufficient amount to be polished during the following CMP process until the step height H is eliminated. Meanwhile, the first layer 220 is preferred to have a thickness sufficient to be a stop layer, protecting the substrate surface 202 from being exposed during the CMP process until the step height His eliminated. According to the embodiment as shown in FIG. 3, the first layer 220 may comprise SiN with a thickness between 10 to 300 Å, and the second layer 240 may comprise SiO2 with a thickness between 200 to 2000 Å. The first layer 220 may act as a stop layer in the following CMP process.

In the following description, the non-planar substrate surface 202 will be planarized by means of a CMP process to provide a substantially flat top surface which is preferred for following processes to be performed thereon.

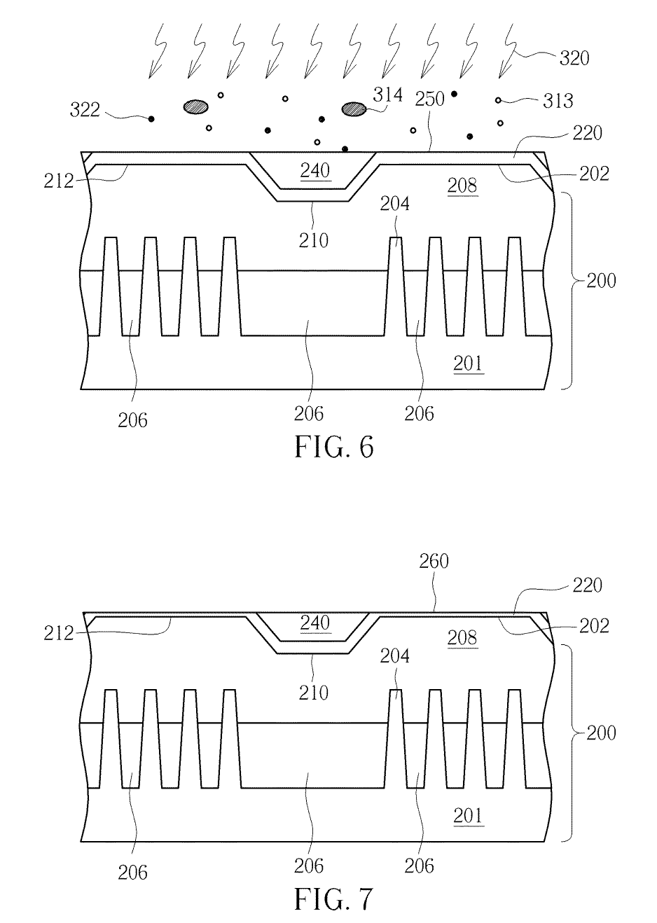

Please refer to FIG. 4 and FIG. 5. As shown in FIG. 4, a first polishing operation 310 is performed on the substrate 200, more particularly, on the top surface of the second layer 240. The first polishing operation 310 may be carried out on the first platen 18 of the CMP platform 10 as shown in FIG. 1. According to the embodiment, the first polishing operation 310 may be a hybrid CMP process employing a first slurry comprising abrasive particles 312 and having high-selectivity between the first layer 220 and the second layer 240. The abrasive particles 312 may attack and remove materials with the assistance from the reactive chemical additives of the first slurry and the relative movement of the polish pad (not shown) and the substrate 200. The abrasive particles 312 may comprise ceria (CeO₂), silica (SiO₂) or aluminum oxide (Al₂O₃) or other suitable materials. According to one embodiment, the abrasive particles 312 may comprise ceria (CeO₂). According to a preferred embodiment, the ratio of the removal rates of the first layer 220 to the second layer 240 during the first polishing operation 310 is around 1:40.

Please refer to FIG. 5. According to the embodiment, the first polishing operation 310 continues to polish the top surface of the second layer 240 until a first polished surface 250 exposing a portion of the first layer 220 is obtained. The first polished surface 250 is substantially a planar surface composed by the exposed portion of the first layer 220 and the remaining second layer 240 wherein the top surfaces of the exposed portion of the first layer 220 and the remaining second layer 240 are flush with each other. The remaining second layer 240 may serve as a filling material to fill up the recess regions 210 of the substrate surface 202. It is noteworthy that none of the substrate 200 is exposed from the first polished surface 250.

The planarization of the first polished surface 250 may be achieved in two stages. First, the high topography of the top surface 241 of the second layer 240 may be polished first and be removed faster than the low topography, therefore the step height H may be gradually eliminated. Second, by using the first slurry with high selectivity between the first layer 220 and the second layer 240, the first layer 220 which has much slower removal rate during the first polishing operation 310 may serve as a stop layer to avoid over-polishing and so that better cross substrate uniformity is obtained.

During the first polishing operation 310, by-products such as pieces of removed materials 313 and particles 314 comprising additives of the first slurry are generated. As shown in FIG. 5, some particles 314 may be attached onto the obtained first polished surface 250, especially near the border between the first layer 220 and the second layer 240. The attached particles 314 may comprise polymers which are hard to be removed by, for example, a conventional wet clean (solvent clean) method. The existence of the attached particles 314 may cause defects in the final fabricated structures.

Please refer to FIG. 6 and FIG. 7. Subsequently, a second polishing operation 320 is performed on the first polished surface 250 for a pre-determined period of time. The second polishing operation 320 may be carried out on the second platen 20 of the CMP platform 10 as shown in FIG. 1. According to the embodiment, the second polishing operation 320 may be a buff polish operation employing a second slurry comprising abrasive particles 322 and having low selectivity between the first layer 220 and the second layer. The abrasive particles 322 may comprise ceria (CeO₂), silica (SiO₂) or aluminum oxide (Al₂O₃) or other suitable abrasives. According to one embodiment, the abrasive particles 322 may comprise silica (SiO₂). The ratio of the removal rates of the first layer 220 to the second layer 240 is around 1:1.2, preferably, 1:1. According to the embodiment, the removal rates of the first layer 220 and the second layer 240 are both around 0 to 15 Å per second. As shown in FIG. 7, after the second polishing operation 320, a second polished surface 260 is obtained.

It is one feature of the present invention that the particles 314 attached on the first polished surface 250 may be effectively removed by the second polishing operation 320. It may be achieved by the abrasive particles 322 with the assistance of chemical reaction and relative movement of the substrate 200 and the polishing pad (not shown). Additionally, during the second polishing operation 320, an upper portion of the exposed first layer 220 and the second layer 240 may be removed therefore the particles 314 attached thereon may be removed simultaneously. According to one embodiment, the second polishing operation 320 is performed for a short period of time, such as 5 seconds, and the removed amounts of the first layer 220 and the second layer 240 are less than 75 Å. In a preferred embodiment, the removed amount is less than 30 Å. In the preferred embodiment when the removal amount of the first layer 220 and the second layer 240 are less than 30 Å, the first polished surface 250 and the second polished surface 260 may be considered to be in a same horizontal level. When performing the second polishing operation 320 on the first polished surface 250, step height between the top surfaces of the exposed portion of the first layer 220 and the remaining second layer 240 which are substantially flush with each other may be avoided by using the second slurry with low selectivity between the first layer 220 and the second layer 240. In other words, the second polished surface 260 is substantially a planar surface composed by the exposed portion of the first layer 220 and the remaining second layer 240 wherein the top surfaces of the exposed portion of the first layer 220 and the remaining second layer 240 are flush with each other. The planarization obtained after the first polishing operation 310 is maintained during the removal of the attached particles 314. It is noteworthy that none of the substrate is exposed from the second polished surface 260.

Please refer to FIG. 8. After the second polishing operation 320, a third polishing operation 330 and a wet clean operation 340 may be performed on the second polished surface 260. The third polishing operation 330 may be carried out on the third platen 22 of the CMP platform 10 as shown in FIG. 1. During the third polishing operation 330, deionized water (DIW) may be applied onto the polishing pad (not shown) and the second polished surface 260 to remove residual slurry thereon. The removal rate of the first layer 220 and the second layer 240 during the third polishing operation 330 is essentially zero.

The wet clean operation 340 may be carried out in the cleaner 16 as shown in FIG. 1. Chemicals such as ammonium hydroxide (NH₄OH), hydrogen peroxide (H₂O₂), hydrofluoric acid (HF) or a combination thereof may be used in the wet clean operation 340. Remaining particles, such as small inorganic particles, may be removed by the wet clean operation 340.

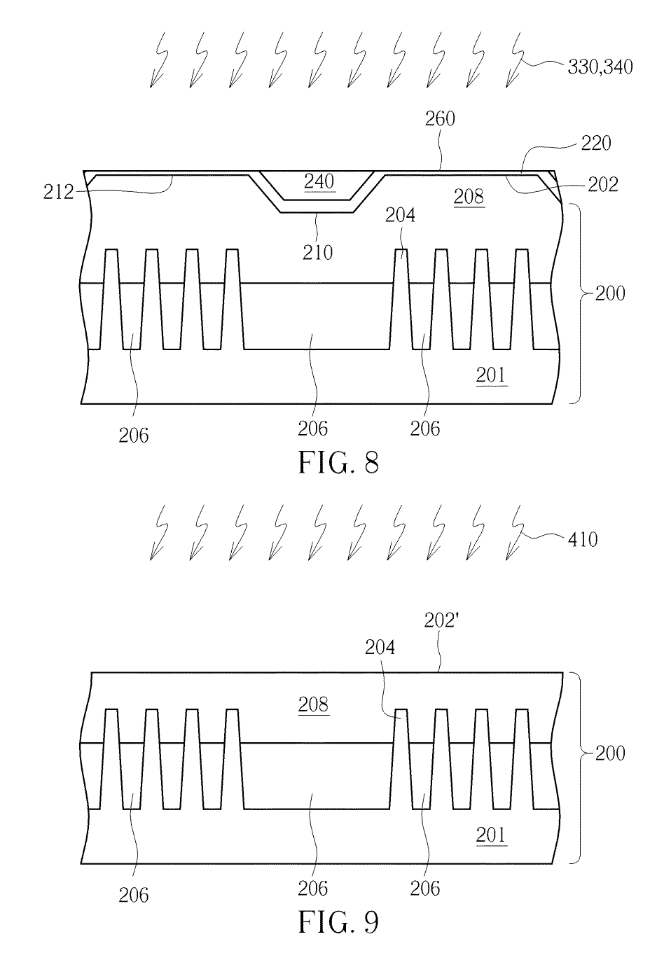

Please refer to FIG. 9. According to the embodiment, an additional non-selective etching back step 410 may be performed on the second polished surface 260. The non-selective etching back step 410 may be carried out in, for example, a dry etching chamber. During the non-selective etching back step 410, the first layer 220, the second layer 240 and a top portion of the substrate 200 is removed in an undifferentiated manner with the same removal rates. The first layer 220 and the second layer 240 may be completely removed and the substrate 200 with a substantially planar substrate surface 202′ is obtained therefrom. According to the embodiment, the substrate surface 202′ is the top surface of the material layer 208. Subsequent semiconductor fabrication process may be performed on the planar substrate surface 202′, such as patterning process or implantation process, and is not illustrated herein for the sake of simplicity.

FIG. 10 and FIG. 11 illustrate another embodiment of the present invention in which the first layer is formed non-continuously on the substrate surface. As shown in FIG. 10, a substrate 500 having a non-planar top surface 502 is provided with a first layer 520 disposed only on the high topography regions of the top surface 502. A second layer 540 is formed covering the first layer 520 and the substrate 200. The second layer 540 is in direct contact with the substrate 500 in the high topography regions which are not covered by the first layer 520. The substrate 500 may undergo a CMP process comprising the first polishing operation, the second polishing operation and the third polishing operation as illustrated previously to obtain a planar top surface 560, as shown in FIG. 11, with reduced attached particles.

Through the method provided by the present invention, a substrate with a substantially planar top surface on which further structures of a semiconductor device may be formed is obtained with reduced attached particles. Therefor structure defects of the semiconductor device may be reduced and the yield may be improved.

Those skilled in the art will readily observe that numerous modifications and alterations of the device and method may be made while retaining the teachings of the invention. Accordingly, the above disclosure should be construed as limited only by the metes and bounds of the appended claims.

1. A method of fabricating a semiconductor structure, comprising:
providing a substrate surface and a first layer disposed on the substrate surface;
forming a second layer covering the first layer wherein the materials of the first layer and the second layer are different;
performing a first polishing operation on the second layer until a first polished surface exposing a portion of the first layer is obtained, wherein the first polishing operation uses a first slurry having high-selectivity between the first layer and the second layer; and
performing a second polishing operation on the first polished surface to obtain a second polished surface, wherein an upper portion of the exposed portion of the first layer is removed and none of the substrate surface is exposed from the first polished surface and the second polished surface, wherein the second polishing operation uses a second slurry having low-selectivity between the first layer and the second layer.

2. The method of fabricating a semiconductor structure according to claim 1, wherein the first layer comprises silicon nitride (SiN), silicon oxynitride (SiON), SiCN, SiOCN or a combination thereof.

3. The method of fabrication a semiconductor structure according to claim 1, wherein the second layer comprises silicon oxide (SiO2).

4. The method of fabricating a semiconductor structure according to claim 1, wherein the thickness of the removed upper portion of the first layer during the second polishing operation is less than 75 Å.

5. The method of fabricating a semiconductor structure according to claim 1, wherein the substrate surface has a non-planar topography comprising plateau regions and recess regions.

6. The method of fabricating a semiconductor structure according to claim 5, wherein first layer conformally and completely covers the substrate surface and the second layer is not in direct contact with the substrate surface.

7. The method of fabricating a semiconductor structure according to claim 5, wherein the first layer is not continuous and only covers a portion of the substrate surface and the second layer is in direct contact with the portions of the substrate surface which is not covered by the first layer.

8. The method of fabricating a semiconductor structure according to claim 5, wherein the first polished surface further comprises a surface of the second layer.

9. The method of fabricating a semiconductor structure according to claim 8, wherein the second layer serves as a filling material to fill up the recess portion of the non-planar substrate surface.

10. The method of fabricating a semiconductor structure according to claim 8, wherein a portion of the second layer is removed during the second polishing operation.

11. The method of fabricating a semiconductor structure according to claim 10, wherein the removed thickness of the second layer during the second polishing operation is less than 75 Å.

12. The method of fabricating a semiconductor structure according to claim 1, wherein a particle is formed and adhered onto the first polished surface after the first polishing operation.

13. The method of fabricating a semiconductor structure according to claim 12, wherein the particle is completely removed by the second polishing operation.

14. The method of fabricating a semiconductor structure according to claim 13, further comprising a wet clean operation after the second polishing operation.

15. The method of fabricating a semiconductor structure according to claim 14, wherein the wet clean comprises using ammonium hydroxide (NH4OH), hydrogen peroxide (H2O2), hydrofluoric acid (HF) or a combination thereof.

16. The method of fabricating a semiconductor structure according to claim 1, wherein a slurry comprising cerium oxide (CeO2) abrasive is used in the first polishing operation, and another slurry comprising silicon oxide (SiO2) abrasive is used in the second polishing operation.

17. The method of fabricating a semiconductor structure according to claim 1, wherein the first layer serves as a stop layer for the first polishing operation.
